(19) United States
(12) Patent Application Publication
(10) Pub. No.: US 2025/0105112 A1
(43) Pub. Date: Mar. 27, 2025

(54) ELECTRONIC PACKAGE WITH INTEGRAL SEAL

(71) Applicant: Navitas Semiconductor Limited, Dublin (IE)

(72) Inventor: Oseob Jeon, Seoul (KR)

(73) Assignee: Navitas Semiconductor Limited, Dublin (IE)

(21) Appl. No.: 18/893,587

(22) Filed: Sep. 23, 2024

Related U.S. Application Data
(60) Provisional application No. 63/584,830, filed on Sep. 22, 2023.

(51) Int. Cl. H01L 23/498; H01L 23/10; H01L 23/31; H01L 23/367; H01L 25/10

(52) U.S. Cl. CPC H01L 23/49811; H01L 23/10; H01L 23/3675; H01L 25/105; H01L 23/3107

(57) ABSTRACT

An electronic package includes a plurality of signal pins, a substrate electrically connected to each pin of the plurality of signal pins and a base comprising a plurality of apertures. Each respective pin of the plurality of signal pins extends through a respective aperture of the plurality of apertures. A seal is disposed in each respective aperture of the plurality of apertures and contacts a peripheral region of each respective signal pin of the plurality of signal pins.

### CROSS-REFERENCE TO RELATED APPLICATIONS

This application claims priority to U.S. provisional patent application Ser. No. 63/584,830, for “ELECTRONIC PACKAGE WITH INTEGRAL SEAL” filed on Sep. 22, 2023, the contents of which are incorporated herein by reference in their entirety for all purposes.

### FIELD

The present invention relates generally to electronic devices and in particular to electronic devices enclosed in protective packaging.

### BACKGROUND

In semiconductor technology, electronic devices can be enclosed in packaging. The electronic device can be electrically connected to an external device (e.g., a circuit board) using signal pins. The signal pins can extend from either side of the electronic component and can be formed at right angles to interface with the external device. Electronic devices that include signal pins that extend from the sides of an electronic package may require added circuit board space which can reduce a density of electronic packages that can be attached to the external device, especially when relatively high clearance or creepage requirements are needed.

### SUMMARY

In some embodiments an electronic package comprises a plurality of signal pins, a substrate electrically connected to each pin of the plurality of signal pins, a base comprising and a plurality of apertures, wherein each respective pin of the plurality of signal pins extends through a respective aperture of the plurality of apertures. A respective seal of a plurality of seals is disposed in each respective aperture of the plurality of apertures and contacts a peripheral region of each respective signal pin of the plurality of signal pins. In various embodiments an encapsulant at least partially encapsulates at least a portion of the base and at least a portion of each signal pin of the plurality of signal pins. In some embodiments the respective seal of the plurality of seals further contacts a wall of each respective aperture.

In various embodiments each signal pin of the plurality of signal pins includes a base region and a shoulder region wherein the base region has a first cross-sectional area and the shoulder region has a second cross-sectional area, and wherein the first cross-sectional area is less than the second cross-sectional area. In some embodiments each respective seal comprises a flexible layer that is laminated within a bottom of the respective aperture. In various embodiments the flexible layer comprises silicone, silicone rubber, or elastomer. In some embodiments each signal pin of the plurality of signal pins is configured to be electrically coupled to a signal board and to conduct power or signals to or from the electronic package. In various embodiments each signal pin is configured to be electrically coupled to the signal board by press fit, soldering, or with conductive glue.

In some embodiments each signal pin comprises an enlarged region configured to limit a length of each pin that protrudes beyond the signal board. In various embodiments each signal pin of the plurality of signal pins is configured to be electrically connected to the substrate by press fit, soldering, brazing, or swaging.

In some embodiments an integrated power system comprises a plurality of electronic packages, where each electronic package comprises a plurality of signal pins, a substrate electrically connected to each pin of the plurality of signal pins, a base comprising a plurality of apertures, wherein each respective pin of the plurality of signal pins extends through a respective aperture of the plurality of apertures. A plurality of seals are disposed in each respective aperture of the plurality of apertures and contact a peripheral region of each respective signal pin of the plurality of signal pins.

In various embodiments the integrated power system further comprises a common heatsink wherein each electronic package of the plurality of electronic packages is in contact with the common heatsink. In some embodiments each electronic package of the plurality of electronic packages further comprises an encapsulant at least partially encapsulating at least a portion of the base and at least a portion of each signal pin of the plurality of signal pins. In various embodiments the respective seal of the plurality of seals further contacts a wall of each respective aperture. In some embodiments each signal pin of the plurality of signal pins includes a base region and a shoulder region and the base region has a first cross-sectional area and the shoulder region has a second cross-sectional area, and wherein the first cross-sectional area is less than the second cross-sectional area.

In various embodiments each respective seal comprises a flexible layer that is laminated within a bottom of the respective aperture. In some embodiments the flexible layer comprises silicone, silicone rubber, or elastomer. In various embodiments the integrated power system further comprises a signal board wherein each signal pin of the plurality of signal pins is configured to be electrically coupled to the signal board. In some embodiments each signal pin is configured to be electrically coupled to the signal board by press fit, soldering, or with conductive glue. In various embodiments each signal pin of the plurality of signal pins is configured to be electrically connected to the substrate by press fit, soldering, brazing, or swaging.

### BRIEF DESCRIPTION OF THE DRAWINGS

FIG. 1 is a simplified side view of an integrated power system, according to some aspects of the present application;

FIG. 2 is a simplified side view of an integrated power system, according to some aspects of the present application;

FIG. 3A is a simplified partial cross-sectional view of a power module, according to some aspects of the present application;

FIG. 3B is a simplified bottom view of a the power module shown in FIG. 3A, according to some aspects of the present application; and

FIG. 4 is a simplified partial cross-sectional view of a power module, according to some aspects of the present application.

### DETAILED DESCRIPTION

In the following description, various embodiments will be described. For purposes of explanation, specific configurations and details are set forth in order to provide a thorough understanding of the embodiments. However, it will also be apparent to one skilled in the art that the embodiments may be practiced without the specific details. Furthermore, well-known features may be omitted or simplified in order not to obscure the embodiment being described.

Techniques disclosed herein relate generally to electronic devices. More specifically, techniques disclosed herein relate to electronic devices that are enclosed within an electronic package that protects the electronic device from environmental damage. In some embodiments the electronic device is a semiconductor device that is encased in a molding material and includes one or more signal pins that are electrically connected to the electronic device and extend through the molding material enabling the electronic device to be electrically connected to an external circuit (e.g., circuit board).

Some embodiments have signal pins that extend directly from the bottom surface of the electronic package which enables the electronic package to consume little space on a circuit board (e.g., higher density electronics) and makes the devices easy to press-fit to the circuit board by applying force directly to the top of the electronic package. Further, the length of the signal pins are significantly reduced (as compared to e.g., gullwing devices), thereby reducing the parasitic inductance and capacitance added by the signal pins. To enable molding of the electronic packages a base is installed on the electronic package (e.g., lead frame) before the molding process where the base includes a plurality of apertures that seal around each signal pin. During the molding process the base prevents leakage of mold material in the signal pin regions and the base is “molded” into the electronic package so it becomes an integral part of the electronic device. These features are described in more detail below.

Several illustrative embodiments will now be described with respect to the accompanying drawings, which form a part hereof. The ensuing description provides embodiment(s) only and is not intended to limit the scope, applicability, or configuration of the disclosure. Rather, the ensuing description of the embodiment(s) will provide those skilled in the art with an enabling description for implementing one or more embodiments. It is understood that various changes may be made in the function and arrangement of elements without departing from the spirit and scope of this disclosure. In the following description, for the purposes of explanation, specific details are set forth in order to provide a thorough understanding of certain inventive embodiments. However, it will be apparent that various embodiments may be practiced without these specific details. The figures and description are not intended to be restrictive. The word “example” or “exemplary” is used herein to mean “serving as an example, instance, or illustration.” Any embodiment or design described herein as “exemplary” or “example” is not necessarily to be construed as preferred or advantageous over other embodiments or designs.

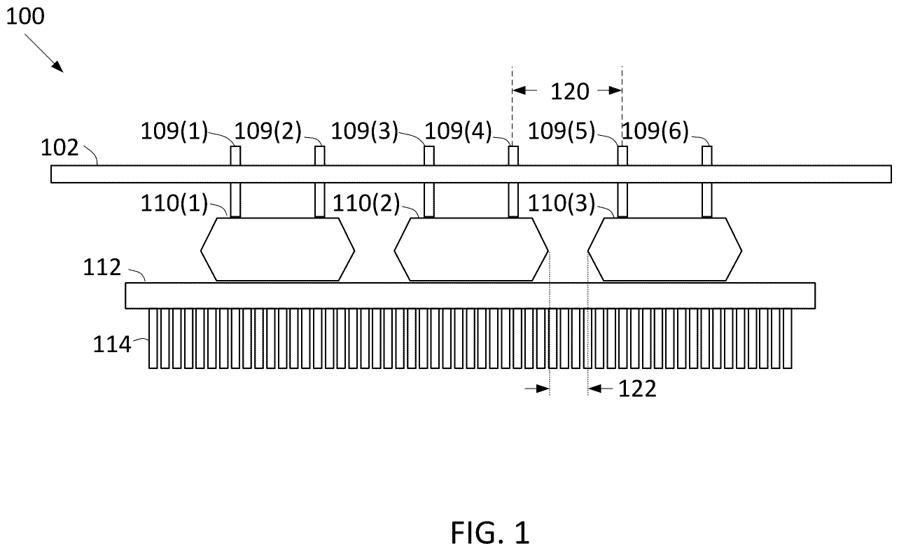

FIG. 1 is an assembly drawing of an integrated power system 100 according to some aspects of the present application. Integrated power system 100 consists of three power modules 110(1), 110(2), and 110(3). A top surface of each power module 110 is attached to a common heat sink 112 via a thermally conductive material (e.g., thermal interface material). In some embodiments the heatsink can have a plurality of pins or fins 114 to radiate heat, while in other embodiments the heatsink can be liquid-cooled. Each module 110 has one or more conductive pins 109 connected to it and extending from a bottom surface of the respective module. For example, as shown in FIG. 1, power module 110(1) has two pins 109(1) and 109(2), power module 110(2) has two pins 109(3) and 109(4), power module 110(3) has two pins 109(5) and 109(6) connected to it. Although each power module is shown as having two pins each power module can have 3, 4, 5, 6 or more pins. The pins 109 conduct power and/or signals to and from the module 110 and are electrically coupled to the signal board 102 (e.g., circuit board). In some embodiments the pins 109 are press-fit, soldered, conductively glued, etc. to the signal board 102 to form an electrical connection between the one or more electronic devices within each power module 110 and the signal board.

The integrated power system 100 can be any suitable power conversion circuit including half or full-bridge, flyback, asymmetric half-bridge or other suitable circuit. In some embodiments each power module 110 can have one or more semiconductor devices within it including, but not limited to a high side semiconductor switch and a low side semiconductor switch. In some embodiments the semiconductor switches are formed from gallium nitride, silicon carbide, silicon or other suitable semiconductor material. The pins 109 extend vertically out of a bottom surface of the module 110 enabling the modules to be closely spaced. The adjacent pins of adjacent modules, such as e.g., 109(2) and 109(3), are sometimes spaced apart a particular distance 120 to meet certain creepage and/or clearance performance characteristics of the modules and/or system 100. The separation distance 120 between adjacent pins of adjacent modules can lead to separation distance 122 between edges of adjacent modules.

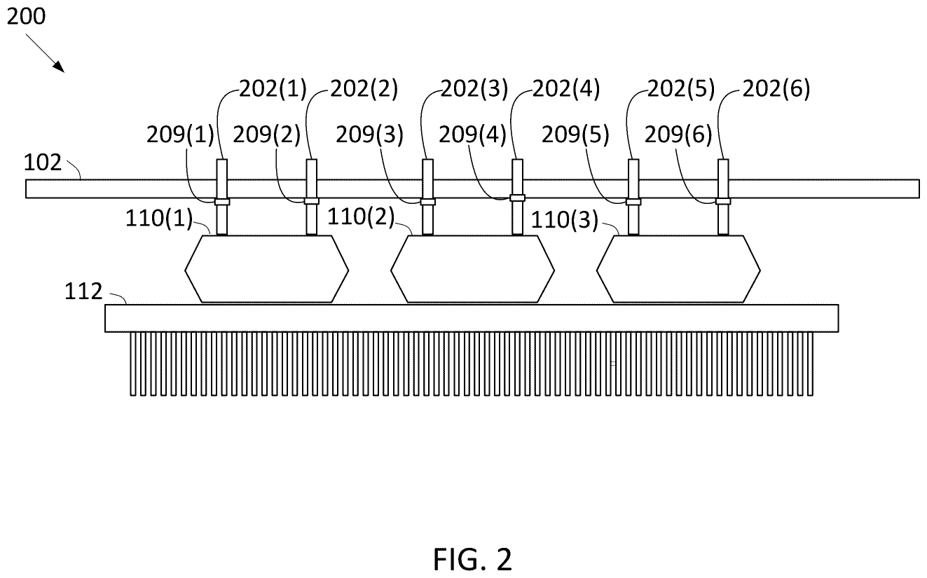

FIG. 2 is an assembly drawing of another integrated power system 200 according to some aspects of the present application. The integrated power system 200 can be the same as integrated power system 100 except pins 202 include enlarged regions 209. In some embodiments enlarged regions 209 can operate as press-fit or soldering “stops” that ensure the pins 202 are inserted to an appropriate depth within signal board 102.

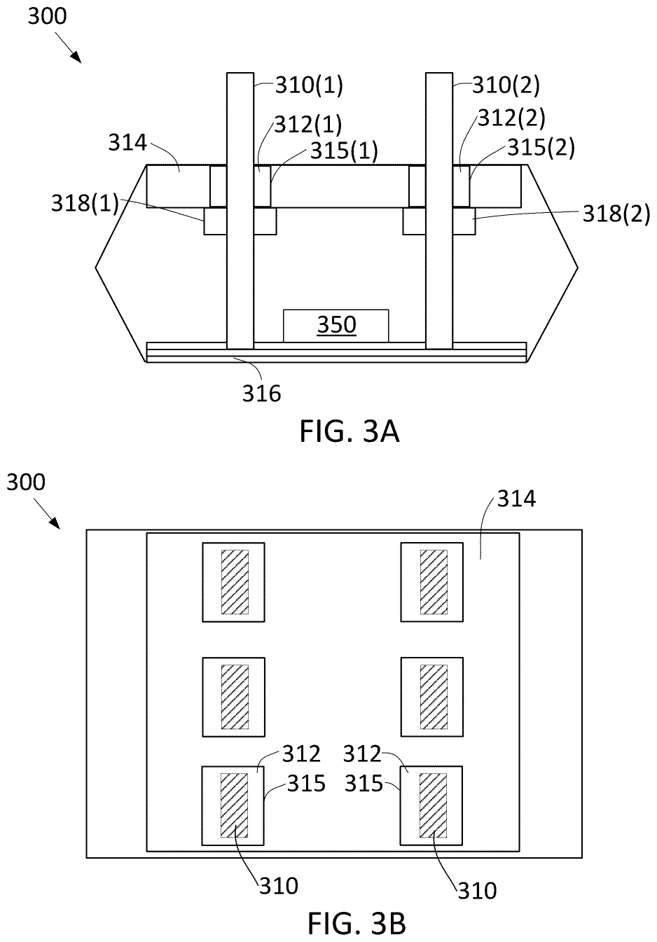

FIG. 3A is a simplified partial cross-sectional view of a power module 300 according to some aspects of the present application and may be used in power system 100 or 200 as disclosed in the previous figures. The power module 300 may be referred to and commonly known as an electronic package. In some embodiments power module 300 is a transfer molded half-bridge module with vertical signal pins 310. Power module 300 has a substrate 316 that has pins 310(1) and 310(2) electrically coupled to it by soldering, press-fit, brazing, swaging, or other suitable process. The substrate 316 can be a multilayer structure and may include an insulating layer sandwiched between two conducting layers such as a ceramic layer between two copper layers. The substrate can also be formed from a single material, such as direct bonded copper (DBC) or a ceramic structure prepared by an active metal brazing (AMB) process. Pins 310 can be electrically coupled to semiconductor device 350 via any suitable interconnect including wirebonds, flip-chip, or other technique. Substrate 316 can be attached to a cold plate or heat exchanger to conduct heat from semiconductor device 350. Pins 310 have a shoulder 318 which can be an enlarged cross-section of the pin. More specifically, pin 310(1) has a shoulder 318(1) and pin 310(2) has a shoulder 318(2). Power module 300 has a base 314 formed from with apertures 315(1) and 315(2) allowing corresponding pins 310 to pass through. The base 314 can be formed from a plastic material, such as polybutylene terephthalate (PBT), a ceramic or other suitable material. A flexible material 312 (e.g., silicone, elastomer, etc.) is positioned within each aperture 315 to form a seal around respective pins 310. The base 314 can be pressed onto pins 310 until a surface of the base 314 comes into contact with the shoulders 318 which hold the base in place. The power module 300 is molded via transfer molding or other suitable process. The seals 315 prevent the mold material from escaping along pins 310 because of the seal formed between the pins and the base 314. Shoulders 381 provide increased sealing between the pins and the base and provide a common insertion stop for the pins. After molding, base 314 becomes an integral part of module 300.

FIG. 3B is a simplified bottom view of a power module 300 shown in FIG. 3A. The power module can include a base 314 with apertures. Although six apertures are depicted in FIG. 3B, the base 314 can include any number of apertures, including a single aperture. Each aperture 315 can include a flexible material 312 disposed therein to seal against each pin 310. The embodiment shown in FIGS. 3A, 3B includes six signal pins, however other embodiments can have fewer or greater number of signal pins and it can be appreciated that the location of the signal pins is flexible and is not restricted to the arrangement shown. Although pins 310 are shown as rectangular in cross-section the pins may have any other suitable cross-section including circular, square, oval, etc.

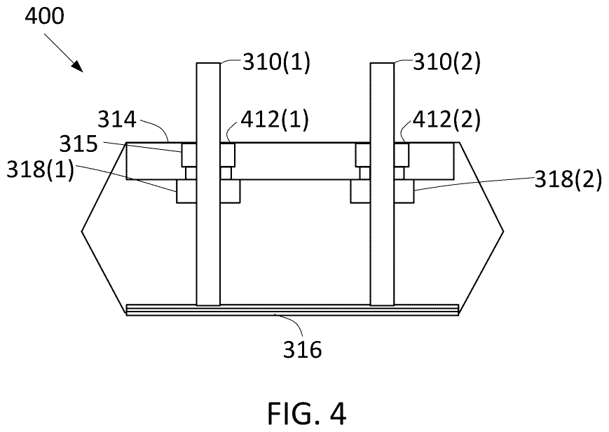

FIG. 4 is a simplified partial cross-sectional view of a power module 400 according to some aspects of the present application. Power module 400 is similar to power module 300 except that the flexible material 312 is replaced with soft seal material 412. In this embodiment soft seal material 412 is thinner than base 314 and does not extend along an entire sidewall of each respective aperture 315. More specifically, in this particular embodiment the aperture has two different perimeters, one larger perimeter that accommodates the seal material 412 and one smaller perimeter that is disposed proximate an interior surface of the base. In some embodiments this may enable soft seal material 412 to be a more rigid material, such as silicon rubber with a relatively high durometer rating, as the portion that must flex is reduced as compared to flexible material 312 of power module 300. In further embodiments, the soft seal material 412 may be a flexible layer that is laminated within base 314, which can include apertures of reduced diameter to seal to the pins. In some embodiments shoulder 318 may be larger than aperture 315 such that the shoulder rests against the base and does not push into the aperture.

Additionally, spatially relative terms, such as “bottom or “top” and the like can be used to describe an element and/or feature's relationship to another element(s) and/or feature(s) as, for example, illustrated in the figures. It will be understood that the spatially relative terms are intended to encompass different orientations of the device in use and/or operation in addition to the orientation depicted in the figures. For example, if the device in the figures is turned over, elements described as a “bottom” surface can then be oriented “above” other elements or features. The device can be otherwise oriented (e.g., rotated 90 degrees or at other orientations) and the spatially relative descriptors used herein interpreted accordingly.

Terms “and,” “or,” and “an/or,” as used herein, may include a variety of meanings that also is expected to depend at least in part upon the context in which such terms are used. Typically, “or” if used to associate a list, such as A, B, or C, is intended to mean A, B, and C, here used in the inclusive sense, as well as A, B, or C, here used in the exclusive sense. In addition, the term “one or more” as used herein may be used to describe any feature, structure, or characteristic in the singular or may be used to describe some combination of features, structures, or characteristics. However, it should be noted that this is merely an illustrative example and claimed subject matter is not limited to this example. Furthermore, the term “at least one of” if used to associate a list, such as A, B, or C, can be interpreted to mean any combination of A, B, and/or C, such as A, B, C, AB, AC, BC, AA, AAB, ABC, AABBCCC, etc.

Reference throughout this specification to “one example,” “an example,” “certain examples,” or “exemplary implementation” means that a particular feature, structure, or characteristic described in connection with the feature and/or example may be included in at least one feature and/or example of claimed subject matter. Thus, the appearances of the phrase “in one example,” “an example,” “in certain examples,” “in certain implementations,” or other like phrases in various places throughout this specification are not necessarily all referring to the same feature, example, and/or limitation. Furthermore, the particular features, structures, or characteristics may be combined in one or more examples and/or features.

In the preceding detailed description, numerous specific details have been set forth to provide a thorough understanding of claimed subject matter. However, it will be understood by those skilled in the art that claimed subject matter may be practiced without these specific details. In other instances, methods and apparatuses that would be known by one of ordinary skill have not been described in detail so as not to obscure claimed subject matter. Therefore, it is intended that claimed subject matter not be limited to the particular examples disclosed, but that such claimed subject matter may also include all aspects falling within the scope of appended claims, and equivalents thereof.

What is claimed is:

1. An electronic package comprising:
a plurality of signal pins;
a substrate electrically connected to each pin of the plurality of signal pins;
a base comprising a plurality of apertures, wherein each respective pin of the plurality of signal pins extends through a respective aperture of the plurality of apertures; and
a plurality of seals, wherein a respective seal of the plurality of seals is disposed in each respective aperture of the plurality of apertures and contacts a peripheral region of each respective signal pin of the plurality of signal pins.

2. The electronic package of claim 1, further comprising an encapsulant at least partially encapsulating at least a portion of the base and at least a portion of each signal pin of the plurality of signal pins.

3. The electronic package of claim 1, wherein the respective seal of the plurality of seals further contacts a wall of each respective aperture.

4. The electronic package of claim 1, wherein each signal pin of the plurality of signal pins includes a base region and a shoulder region and, wherein the base region has a first cross-sectional area and the shoulder region has a second cross-sectional area, and wherein the first cross-sectional area is less than the second cross-sectional area.

5. The electronic package of claim 1, wherein each respective seal comprises a flexible layer that is laminated within a bottom of the respective aperture.

6. The electronic package of claim 5, wherein the flexible layer comprises silicone, silicone rubber, or elastomer.

7. The electronic package of claim 1, wherein each signal pin of the plurality of signal pins is configured to be electrically coupled to a signal board and to conduct power or signals to or from the electronic package.

8. The electronic package of claim 7, wherein each signal pin is configured to be electrically coupled to the signal board by press fit, soldering, or with conductive glue.

9. The electronic package of claim 7, wherein each signal pin comprises an enlarged region configured to limit a length of each pin that protrudes beyond the signal board.

10. The electronic package of claim 1, wherein each signal pin of the plurality of signal pins is configured to be electrically connected to the substrate by press fit, soldering, brazing, or swaging.

11. An integrated power system comprising:
a plurality of electronic packages, each electronic package of the plurality of electronic packages comprising:
a plurality of signal pins;
a substrate electrically connected to each pin of the plurality of signal pins;
a base comprising a plurality of apertures, wherein each respective pin of the plurality of signal pins extends through a respective aperture of the plurality of apertures; and
a plurality of seals, wherein a respective seal of the plurality of seals is disposed in each respective aperture of the plurality of apertures and contacts a peripheral region of each respective signal pin of the plurality of signal pins.

12. The integrated power system of claim 11, further comprising a common heatsink and wherein each electronic package of the plurality of electronic packages is in contact with the common heatsink.

13. The integrated power system of claim 11, wherein each electronic package of the plurality of electronic packages further comprises an encapsulant at least partially encapsulating at least a portion of the base and at least a portion of each signal pin of the plurality of signal pins.

14. The integrated power system of claim 11, wherein the respective seal of the plurality of seals further contacts a wall of each respective aperture.

15. The integrated power system of claim 11, wherein each signal pin of the plurality of signal pins includes a base region and a shoulder region and, wherein the base region has a first cross-sectional area and the shoulder region has a second cross-sectional area, and wherein the first cross-sectional area is less than the second cross-sectional area.

16. The integrated power system of claim 11, wherein each respective seal comprises a flexible layer that is laminated within a bottom of the respective aperture.

17. The integrated power system of claim 16, wherein the flexible layer comprises silicone, silicone rubber, or elastomer.

18. The integrated power system of claim 11, further comprising a signal board and wherein each signal pin of the plurality of signal pins is configured to be electrically coupled to the signal board.

19. The integrated power system of claim 18, wherein each signal pin is configured to be electrically coupled to the signal board by press fit, soldering, or with conductive glue.

20. The integrated power system of claim 11, wherein each signal pin of the plurality of signal pins is configured to be electrically connected to the substrate by press fit, soldering, brazing, or swaging.
